(19) United States
(12) Patent Application Publication
(10) Pub. No.: US 2024/0287272 A1
(43) Pub. Date: Aug. 29, 2024

(54) RADIATIVE COOLING FILM WITH SURFACE PERIODIC MICRO-NANO STRUCTURE AND PREPARATION METHOD

(71) Applicant: Innofocus Photonics Technology Pty Ltd, Victoria (AU)

(72) Inventors: Baohua JIA, Victoria (AU); Han LIN, Victoria (AU)

(21) Appl. No.: 18/579,075

(22) PCT Filed: Apr. 20, 2022
(86) PCT No.: PCT/CN2022/087864

§ 371 Date: Jan. 12, 2024

(30) Foreign Application Priority Data
Jul. 15, 2021 (CN) 202110800547.X

(51) Int. Cl. C08J 7/06; F28F 13/18; G03F 7/00; G03F 7/16; G03F 7/20

(52) U.S. Cl. CPC C08J 7/06; F28F 13/185; G03F 7/0012; G03F 7/161; G03F 7/2002; C08J 2323/12; C08J 2327/06; C08J 2327/14; C08J 2333/12; C08J 2367/02; C08J 2369/00; F28F 2245/06; F28F 2255/20

(57) ABSTRACT

A radiative cooling film with a surface periodic micro-nano structure can be prepared. The radiative cooling film includes a periodic micro-nano structure layer, a polymer film layer and a reflective coating. The periodic micro-nano structure layer, polymer film layer and the reflective coating can be arranged in a top-down order. Alternatively, the polymer film layer, the periodic micro-nano structure layer and the reflective coating are arranged in a top-down order. A radiation refrigeration film controls the absorption and radiation of the radiative cooling film in the visible light and infrared light bands by adding periodic micro-nano structures on the surface of the polymer film layer. It can increase the infrared radiation to effectively improve the radiative cooling performance and has a high market promotion value.

This application requests the priority of the Chinese patent application submitted to the China Patent Office on Jul. 15, 2021, with the application number 202110800547.X and the invention title “A radiative cooling film with surface periodic micro-nano structure and preparation method”, the entire contents of which are incorporated herein by reference.

### TECHNICAL FIELD

The present invention relates to the technical field of radiative cooling, and in particular to a radiative cooling film with a surface periodic micro-nano structure and a preparation method.

### BACKGROUND TECHNIQUE

With the improvement of people's living standards, building energy consumption accounts for an increasing proportion of total energy consumption. Traditional active cooling technology (such as air-conditioning technology) requires energy to remove heat. Not only is it high energy consumption, but the chlorofluorocarbon working fluid used will cause damage to the ozone layer, thus causing environmental pollution problems such as the greenhouse effect and air pollution. Radiative cooling technology is low-energy-consuming and non-polluting. The new passive cooling method has positive significance for cooling, energy saving and environmental protection. It takes advantage of the fact that thermal infrared radiation of a specific wavelength (8-13 μm) can pass through the Earth's atmosphere and escape to outer space without hindrance. Converting the heat from the heat source into infrared rays of specific wavelengths can radiate them to the extremely low temperature of outer space, realize heat exchange between objects and outer space, and achieve the purpose of cooling the object.

At present, radiative technology is widely used in building energy conservation, automobiles, solar cell cooling, outdoor equipment heat dissipation, outdoor equipment cooling, agricultural greenhouses, tents, umbrellas, textiles and other fields. Among the radiative cooling products that have been commercialized, radiative cooling film has a relatively high market share. When used, people usually attach the radiant cooling film to the outer surface of the object to be cooled, such as the exterior wall or roof of a building. Then when the radiant cooling film reflects sunlight, it emits heat in the form of infrared radiation in the atmospheric window band. transmitted to outer space. However, the cooling effect of existing radiative cooling films needs to be further improved.

The above information is presented as background information only to assist in understanding the present disclosure and is not intended to determine or admit whether any of the above may serve as prior art to the present disclosure.

### Contents of the Invention

The invention provides a radiative cooling film with a surface periodic micro-nano structure and a preparation method to solve the shortcomings of the existing technology.

In order to achieve the above objects, the present invention provides the following technical solutions:
In the first aspect, embodiments of the present invention provide a radiative cooling film with a periodic micro-nano structure on the surface. The radiative cooling film includes a periodic micro-nano structure layer, a polymer film layer and a reflective coating; wherein,
The periodic micro-nano structure layer, polymer film layer and reflective coating are arranged in order from top to bottom;
Alternatively, the polymer film layer, the periodic micro-nano structure layer and the reflective coating are arranged in sequence from top to bottom.

Further, in the radiative cooling film with surface periodic micro-nano structure, the periodic micro-nano structure layer is composed of periodic micro-nano structure;

The periodic micro-nano structures are periodically arranged air holes or periodically arranged dielectric pillars.

Further, in the radiative cooling film with a surface periodic micro-nano structure, the width of the periodic micro-nano structure is 3˜8 μm, the period is 6˜12 μm, and the depth is 0.5˜5 μm.

Further, in the radiative cooling film with surface periodic micro-nano structure, the polymer film layer is polyethylene terephthalate, polyvinyl chloride, polycarbonate, polymethyl methacrylate, Either polyvinylidene fluoride or polypropylene.

Further, in the radiative cooling film with surface periodic micro-nano structures, the reflective coating is a metal coating or a dielectric coating.

Further, in the radiative cooling film with surface periodic micro-nano structures, the metal coating is an aluminum coating or a silver coating.

Further, in the radiative cooling film with surface periodic micro-nano structure, the radiative cooling film also includes a protective layer;

The protective layer is located on the surface of the reflective coating away from the polymer film layer or the periodic micro-nano structure layer.

Further, in the radiative cooling film with surface periodic micro-nano structures, the protective layer is an anti-fingerprint coating or a hard coating layer.

In a second aspect, embodiments of the present invention provide a method for preparing a radiative cooling film, which is used to prepare a radiative cooling film having a surface periodic micro-nano structure as described in the first aspect, and the method includes:
Make a photolithography mask;
Apply UV to the surface of the polymer film layer glue;
The UV The glue is exposed to UV light; a developer is used to develop the UV glue;
The developer on the polymer film layer is cleaned to obtain a periodic micro-nano structure layer; a reflective coating layer is plated on the surface of the periodic micro-nano structure layer or the surface of the polymer film layer;

A protective layer is plated on the surface of the reflective coating.

In a third aspect, embodiments of the present invention provide a method for preparing a radiative cooling film, which is used to prepare a radiative cooling film having a surface periodic micro-nano structure as described in the first aspect, and the method includes:
Use laser processing to create patterns on the polymer substrate to obtain a polymer film with periodic micro-nano structure layers;
Coating a reflective coating layer on the surface of the periodic micro-nano structure layer or the surface of the polymer film;
A protective layer is plated on the surface of the reflective coating.

Compared with the prior art, the embodiments of the present invention have the following beneficial effects:
A radiative cooling film with a surface periodic micro-nano structure provided by an embodiment of the present invention and the preparation method controls the absorption and radiation characteristics of the radiative cooling film in the visible and infrared light bands by adding periodic micro-nano structures on the surface of the polymer film layer, thereby increasing the infrared emissivity to effectively improve the radiative cooling performance, and has high marketing value.

### DESCRIPTION OF THE DRAWINGS

In order to explain the embodiments of the present invention or the technical solutions in the prior art more clearly, the following will briefly introduce the drawings needed to describe the embodiments or prior art. Obviously, the drawings in the following description are only some embodiments of the present invention. For those of ordinary skill in the art, other drawings can be obtained based on these drawings without exerting any creative effort.

FIG. 1 is a schematic side view of the structure of a radiative cooling film with a surface periodic micro-nano structure provided in Embodiment 1 of the present invention;

FIG. 2 is a schematic top view of the structure of a radiative cooling film with a surface periodic micro-nano structure provided in Embodiment 1 of the present invention;

FIG. 3 is a schematic side view of the structure of a radiative cooling film with a surface periodic micro-nano structure provided in Embodiment 1 of the present invention;

FIG. 4 is a schematic diagram of the simulated spectral absorbance/emissivity of H6.5P8D2.5 microstructured PET film in the 8-13 μm wavelength range;

FIG. 5 is a schematic diagram of the solar absorptivity (Asun) of H6.5P8D2.5 microstructured PET film;

FIG. 6 is a schematic diagram of the average emissivity on an Ag film with a film thickness between 10 and 100 μm;

FIG. 7 is a schematic diagram of the calculated cooling power of H6.5P8D2.5 microstructured PET films with different thicknesses coated with silver on the back at night (a) and during the day (b);

FIG. 8 is a schematic diagram of the transmission spectrum of the atmosphere at different locations when the amount of water vapor is different. Water 3 mm is shown in black, while water 0R-50 is shown in red;

FIG. 9 is a schematic diagram of the cooling power values at night (a) and during the day (b) of H6.5P8D2.5 microstructured PET film with different thicknesses coated on the back and a flat PET film with different thicknesses coated on the back based on the atmospheric transmittance spectrum of 0R-50 (Hawthorn) water. Schematic diagrams of the cooling power values at night (c) and during the day (d) calculated based on the atmospheric transmission spectrum of 3 mm water;

FIG. 10 is a schematic diagram of the simulated absorptivity (a) in the solar spectrum range and the emissivity (b) in the wavelength range 8-13 μm for different structural depths on PET (0.5 and 5 μm). Schematic representation of the average absorbance (Asun) curve (c) of the solar spectrum and the average emissivity (E@8-13 μm) curve (d) in the wavelength range of 8-13 μm;

FIG. 11 is a schematic diagram showing the calculated cooling power values of H6.5P8 microstructured PET films with different structural depths coated with silver on the back at night (a) and during the day (b);

FIG. 12 is a schematic diagram of the measured absorption/emission spectra of a commercial cooling film (a) and a silver-backed microstructured PET film (b);

FIG. 13 is the calculated microstructure of a commercial cooling film and silver coating at night (a) and during the day (b).

FIG. 14 is a photo of the microstructured PET film before (a) and after (b) silver coating and a photo of the experimental device used for measurement (c);

FIG. 15 is a schematic diagram of the measured temperature and ambient temperature of the microstructured PET film with silver coating on the back at night (a) and during the day (b). Ta is the ambient temperature, and Tfilm is the cooling film temperature;

FIG. 16 is a schematic diagram of the temperature test box;

FIG. 17 is a schematic diagram of the temperature measurement system;

FIG. 18 is the measurement result on a cloudy day;

FIG. 19 is the cloudy measurement result;

FIG. 20 is the clear day measurement result;

FIG. 21 is the schematic diagram of the measurement box;

FIG. 22 is a photo of the cooling power measurement system;

FIG. 23 is the power measurement result (cloudy);

FIG. 24 is the power measurement result (sunny);

FIG. 25 is the cooling power measurement result at night;

FIG. 26 is the cooling power at fixed operating temperature;

FIG. 27 is a radiative cooling film with surface periodic micro-nano structures provided in Embodiment 2 of the present invention and its preparation method;

FIG. 28 is a radiative cooling film with surface periodic micro-nano structures and a preparation method provided in Embodiment 3 of the present invention.

### DETAILED IMPLEMENTATION METHODS

The technical solution of the present invention will be further described below with reference to the accompanying drawings and through specific implementation modes.

### Embodiment 1

In view of the above-mentioned shortcomings of existing radiative cooling films, the applicant is engaged in this industry with many years of rich practical experience and professional knowledge in the industry, and the application of academic theory, we actively conduct research and innovation, hoping to create technologies that can solve the shortcomings of existing technologies and make radiative cooling films more practical. After continuous research, design, and repeated testing of samples and improvements, the invention was finally created with real practical value.

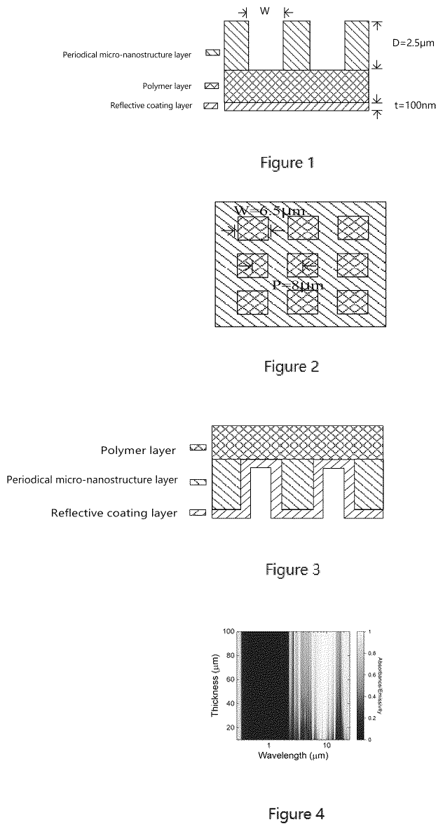

Please refer to FIGS. 1 to 3. Embodiments of the present invention provide a radiative cooling film with surface periodic micro-nano structures. The radiative cooling film includes a periodic micro-nano structure layer, a polymer film layer and a reflective coating; wherein,

The periodic micro-nano structure layer, polymer film layer and reflective coating are arranged in order from top to bottom, as shown in FIGS. 1 to 2;

Alternatively, the polymer film layer, the periodic micro-nano structure layer and the reflective coating are arranged in sequence from top to bottom, as shown in FIG. 3.

It should be noted that the cooling power of the radiation cooling film can reach 122 W/m² on a clear day, which can improve the power density of the current radiative cooling film. Due to its flexibility and easy application, it can be widely used in wearable cooling devices, foldable cooling devices, retractable cooling curtains, car clothing, and building surface cooling applications.

In this embodiment, the periodic micro-nano structure layer is composed of periodic micro-nano structures;

The periodic micro-nano structure may be periodically arranged air holes, or periodically arranged dielectric pillars, or may be any periodically distributed graphics, including graphics with different periods nested in each other. The periodic micro-nano structure can be processed using photoresist (mainly ultraviolet photoresist, or UV glue) using photolithography methods, or directly processed on the polymer substrate using laser ablation technology, and controlled by structural parameters to control the visible light transmittance and infrared emissivity spectrum of the material.

Preferably, the width of the periodic micro-nano structure is 3˜8 μm, preferably 6.5 μm, the period is 6˜12 μm, preferably 8 μm, and the depth is 0.5˜5 μm, preferably 2.5 μm.

In this embodiment, the polymer film layer is a common polymer, and its optional range includes polyethylene terephthalate, polyvinyl chloride, polycarbonate, polymethyl methacrylate, polypyrene Vinyl fluoride, polypropylene, etc.

In this embodiment, the reflective coating is a metal coating or a dielectric coating, wherein the metal coating can be an aluminum coating or a silver coating, used to reflect visible light. Of course, any other metal with high reflectivity can also be selected, which is not limited in this embodiment.

In this embodiment, the radiative cooling film further includes a protective layer for protecting the surface of the radiative cooling film;

The protective layer is located on the surface of the reflective coating on the side away from the polymer film layer or the periodic micro-nano structure layer, but no matter which one, it is adhered to the reflective coating.

Preferably, the protective layer is an anti-fingerprint coating (AF layer) or a hard coating layer (HC layer).

It should be noted that in this embodiment, the microstructured PET film is processed according to its different structural dimensions.

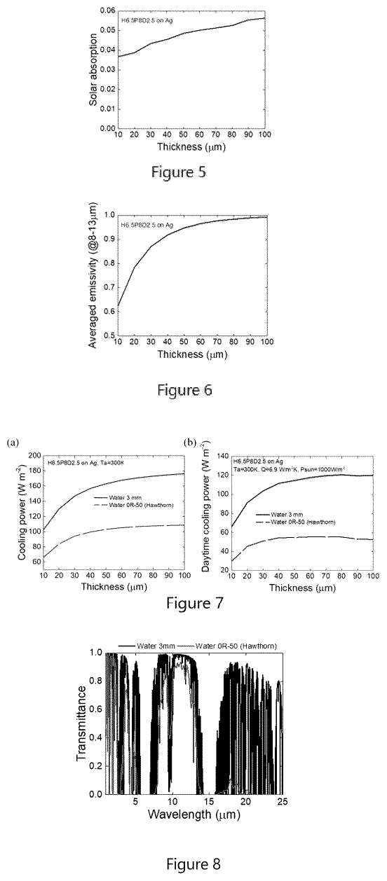

It should be noted that this embodiment marks the microstructured PET film according to its different structural dimensions; for example, a film with a microstructure having a pore width of 6.5 μm, a period of 8 μm, and a depth of 2.5 μm is named “H6.5P8D2.5”. FIG. 4 shows the simulated absorption spectra of H6.5P8D2.5 microstructured PET films with different thicknesses on a 200 nm Ag film. Then, the solar absorbance (Asun) (FIG. 5) and average emissivity (FIG. 6) of H6.5P8D2.5 in the wavelength range from 8 to 13 μm (E @8-13 μm) were calculated. Based on simulations, the absorption spectra of microstructured PET films with different thicknesses on silver films are shown in FIG. 4. As shown in FIGS. 5 and 6, when the thickness of the PET film of H6.5P8D2.5 increases from 10 microns to 100 microns, Asun and E@8-13 μm will gradually increase from 3.7% to 5.6% and from 62.4%, respectively. to 99.2%. The Asun and E@8-13 μm of H6.5P8D2.5 microstructured PET film with 50 μm thickness of back silver coating are 4.85% and 94.7% respectively.

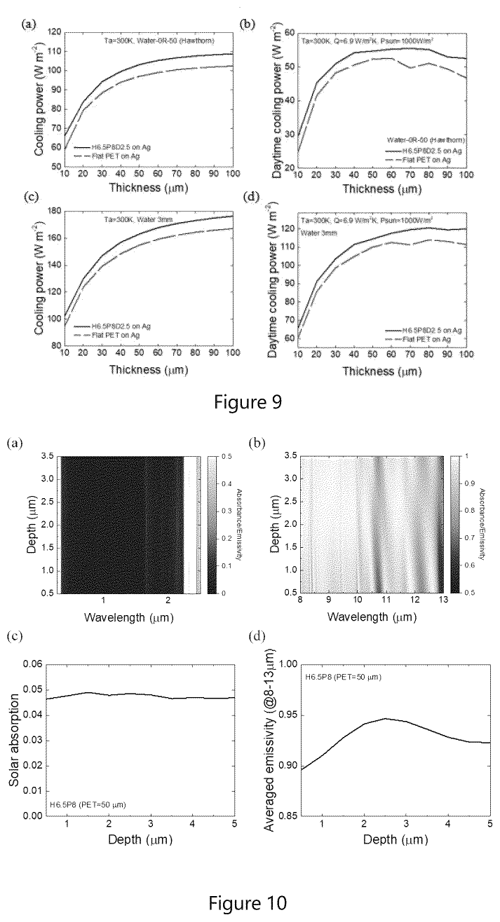

Based on the atmospheric transmission spectrum and simulated absorption spectrum, the cooling power of H6.5P8D2.5 microstructured PET films with different thicknesses coated with silver on the back was calculated. FIG. 7 shows the calculated cooling power of H6.5P8D2.5 microstructured PET films with different thicknesses coated with silver on the back at an ambient temperature of 300K at night and during the day, respectively. Here the conduction and convection coefficients are set to 6.9 W/m²K. In addition, it is assumed that the sunlight power density during the day is 1000 Wm-2. Calculated from the atmospheric transmission spectra of 3 mm water (black line in FIG. 8) and 0R-50 (Hawthorn) water (red line in FIG. 8), when the thickness of H6.5P8D2.5 microstructured PET film increases from 10 microns At 100 micron, the cooling power at night will gradually increase from 102.4 Wm⁻² to 176.3 Wm⁻², and 66.1 Wm⁻² to 108.7 Wm⁻² respectively ((a) in FIG. 7). In addition, based on the atmospheric transmission spectra of 3 mm water (black line in FIG. 8) and 0R-50 (Hawthorn) water (red line in FIG. 8), it is calculated that the thickness of the back silver plating of H6.5P8D2.5 is within 10 and the daytime cooling power of microstructured PET films in the range of 100 μm are in the range of 65.7 Wm⁻² to 120 Wm⁻² and 29.5 Wm⁻² to 55.4 Wm⁻², respectively ((a) in FIG. 7). Calculated based on the atmospheric transmission spectrum of 3 mm water, the cooling power of the H6.5P8D2.5 microstructured PET film with a silver coating on the back and a thickness of 50 μm is 163.1 Wm⁻² and 114.5 Wm⁻² at night and during the day, respectively. On the other hand, based on calculations based on the 0R-50 (Hawthorn) atmospheric transmission spectrum, the cooling power of the H6.5P8D2.5 microstructured PET film with a silver coating on the back and a thickness of 50 m at night and during the day is 103.1 Wm⁻² and 56.6 Wm⁻² respectively. Taking the flat film without structure as a reference, it can be seen that the PET film with microstructure is higher than the PET film without microstructure ((a) and (b) in FIG. 9). Therefore, based on the atmospheric transmission spectrum of water 0R-50 (Hawthorn) (red line in FIG. 8), the backside silver-coated H6.5P8D2.5 microstructured PET film performs better for nighttime and daytime cooling than a flat PET film of the same thickness. The power is about 2.3 Wm⁻² to 7 Wm⁻² higher ((a) and (b) in FIG. 9). Based on the atmospheric transmission spectrum of 3 mm water ((a) in FIG. 7), the nighttime and daytime cooling power of the H6.5P8D2.5 microstructured PET film coated with silver is approximately 3.5 Wm⁻² to 9.1 Wm⁻² higher than that of a flat PET film of the same thickness. ((c) and (d) in FIG. 9). Therefore, by manufacturing microstructures on the PET film, the cooling power of the back-coated PET film can be effectively increased.

Optimization of structural parameters of microstructured PET film with silver coating on the back:

In the simulation, the hole width (H), period (P), thickness of PET film and thickness of Ag film were fixed to 6.5 μm, 8 μm, 50 μm and 200 nm, respectively, and only the depth of the microstructure was changed. FIGS. 10 (a) and (b) shows the simulated absorbance in the solar spectral range and the simulated emissivity spectrum in the wavelength range of 8-13 μm of H6.5P8 microstructured PET films with different structural depths coated with silver on the back. As shown in (a) and (b) in FIG. 10, in two wavelength ranges, the absorption/emission spectrum of the microstructured PET film coated with silver on the back slightly changes with the increase of the microstructure depth. Then, the solar absorbance (Asun) of H 6.5 P 8 microstructure with different depths ((c) in FIG. 10) and at 8 and 13 μm (E @ 8-13 μm) average emissivity in the wavelength range ((d) in FIG. 10). As shown in (c) and (d) in FIG. 10, when the depth of H 6.5 P 8 increases from 0.5 μm to 5 μm, the changing range of Asun and E @ 8-13 μm 4.6% to 4.9% and 89.6% to 94.7%, respectively. The H6.5P8D microstructured PET film with a backside silver coating of 50 μm has the highest average emissivity of 94.7% in the wavelength range of 8-13 μm at a depth of 2.5 μm.

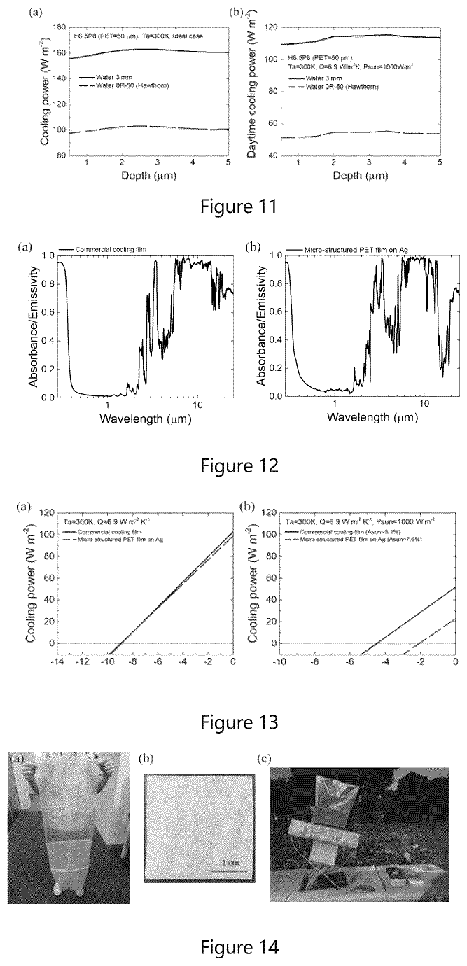

Next, based on the atmospheric transmission spectrum and simulated absorption spectrum, the cooling power of the H6.5P8 microstructured PET film with back-side silver coating was calculated with different depths. (a) and (b) in FIG. 11 show the calculated cooling power of H6.5P8 microstructured PET films with different structural depths coated with silver on the back at night and during the day at an ambient temperature of 300 K, respectively. Here the conduction and convection coefficients are set to 6.9 W/m²K. In addition, it is assumed that the sunlight power density during the day is 1000 Wm⁻². Calculated from the atmospheric transmission spectra of 3 mm water (black line in FIG. 8) and 0R-50 (Hawthorn) water (red line in FIG. 8) when the depth of H6.5P8 microstructure is in the range of 0.5 to 5 μm, the daytime cooling power will gradually increase from 155.5 Wm⁻² to 163.1 Wm⁻². The cooling power at night is 97.6 Wm⁻² and gradually increases to 103.1 Wm⁻² ((a) in FIG. 11). In addition, based on the atmospheric transmission spectra of water 3 mm (red line in FIG. 8) and water 0R-50 (Hawthorn) (red line in FIG. 8), the structure with different depths and backside silver coating can be evaluated. The daytime cooling power of H6.5P8 microstructured PET film in 0.5-5 μm ranges from 109.2 Wm⁻² to 115.5 Wm⁻² and 51.2 Wm⁻² to 55.3 Wm⁻² ((b) in FIG. 11). Based on these results, the difference in daytime cooling power of microstructured PET films with microstructure depth in the range of 2.5 μm to 3.5 μm coated with silver on the back side is less than 0.7 Wm⁻². Therefore, there is a large tolerance for error in the depth of the proposed microstructure during fabrication.

Comparison of the present invention with commercial radiant cooling films:

FIGS. 12 (a) and (b) show the absorption/emission spectra of a commercial cooling film and a microstructured PET film with silver coating on the back (experimentally produced), respectively. Commercial cooling films have significant differences in solar absorptivity (Asun), and the average emissivity in the wavelength range of 8 and 13 μm (E @ 8-13 μm) is 5.1% and 94%, respectively. In addition, the Asun and E @ 8-13 μm of microstructured PET with silver coating on the back are 7.6% and 91.5%, respectively. The Asun and E@ 8-13 μm of the microstructured PET with back silver coating obtained from the measured absorption/emissivity are higher or lower than the simulation results, respectively. This result is attributed to the insufficient quality of the silver film deposited on the back of the microstructured PET film.

Next, the cooling power of commercial cooling films and back-side silver-coated microstructured PET films was calculated based on the atmospheric transmission spectrum and measured absorptance/emissivity spectra of water 0R-50 (Hawthorn). (a) and (b) in FIG. 13 show the cooling power of commercial cooling film and back-side silver-coated microstructured PET film at night and daytime at an ambient temperature of 300 K, respectively. Here the conduction and convection coefficients are set to 6.9 W/m²K. In addition, it is assumed that the sunlight power density during the day is 1000 Wm⁻². At night, the calculated cooling power of the backside silver-coated microstructured PET is very close to that of commercial cooling films. Furthermore, at night, the maximum temperature difference of the backside silver-coated microstructured PET was slightly larger than that of the commercial cooling film. However, the calculated cooling power of the back-side silver-coated microstructured PET film during the day is lower than that of the commercial cooling film because the backside silver-coated microstructured PET film has a higher absorptivity in the solar spectrum.

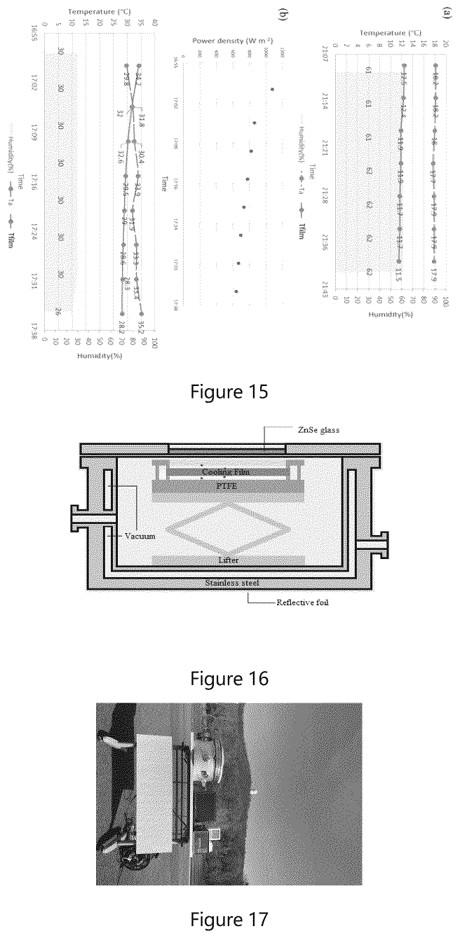

(a)˜(c) in FIG. 14 show the photos of the microstructured PET film before and after silver coating and the experimental device used for measurement, respectively. As shown in (a) in FIG. 14, large-area microstructured PET films can already be fabricated. The back side of the microstructured PET film was silver-coated ((b) in FIG. 14) and placed into the device ((c) in FIG. 14) to test its cooling performance. (a) and (b) in FIG. 15 show the temperature (Tfilm) and ambient temperature (Ta) of the back-side silver-coated microstructured PET film measured at night and during the day, respectively. As shown in (a) in FIG. 15, the temperature of the microstructured PET film with silver coating on the back is about 6° C. lower than the ambient temperature at night. In addition, under sunlight irradiation with power densities of 634.4 Wm⁻² and 1078.2 Wm⁻², the temperature of the microstructured PET film with silver coating on the back was 2.2 to 5.1° C. lower than the ambient temperature. Therefore, the microstructured PET film with silver coating on the back shows good cooling performance both at night and during the day.

### Measurement of Cooling Effect Under Vacuum Conditions:

### Temperature Measurement Experiment

### 1. Device Introduction

The radiative cooling film temperature test chamber is mainly composed of a film test area unit, a lifting platform, a shell and other parts. The schematic diagram of the overall structure is shown in FIG. 16.

The shell material is 316 L stainless steel and is divided into two parts. The upper and lower parts are connected by flanges. There is a 100 mm×100 mm window on the top of the upper cover part, which is used to place Zn—Se glass. The glass size is 100 mm×100 mm×5 mm. The infrared transmittance of ZnSe is 75%-80%, and it can withstand high pressure. The lower part is designed with a double-layer structure and can measure both vacuum and non-vacuum conditions inside. The entire outer surface is wrapped in aluminum foil. The cooling radiation film is fixed by a polytetrafluoroethylene (PTFE) clamp with a large thermal resistance. Except for the edge clamping part, the upper and lower surfaces of the film are not in contact with other structures to ensure that the true temperature of the upper and lower surfaces of the film can be measured to avoid Heat conduction producing temperature losses. The fixture is placed on the lifting table, which is a three-axis manual moving table. When the Z-axis is adjusted to the highest position, the radiative cooling film should be as close as possible to the Zn—Se glass window to control the alignment between the film and the top glass of the shell and the distance between the film and the glass. The red dots in FIG. 16 are the locations of the thermocouples.

### 2. Experimental Methods

We clamp the 120 mm×120 mm radiative cooling film to be measured on the fixture and arrange the K-type thermocouples according to the layout shown in FIG. 16, then measure the ambient temperature on the upper surface, the lower surface of the radiative cooling film, the location under the film not exposed to sunlight, and the temperature on the film respectively.

The ambient temperature of the location exposed to sunlight was recorded in real-time with a temperature collector (Fluke SERIES III). While measuring the temperature, the solar irradiance data was collected through a light collector (Jianda Nishina), and the data was recorded using the supporting software on the laptop. The real-time humidity was measured and recorded through a hygrometer (Jianda Nishina). The overall measurement system is shown in FIG. 17.

We place the entire system in an open field. Before starting each experiment, we open the upper cover of the measurement box and leave it for half an hour to make the internal temperature of the box close to the ambient temperature. We open all data acquisition equipment and then close the lid to block the upper window, there is a heating process at this time. After the internal temperature of the box has stabilized, remove the obstruction on the window, record the time, and start the experiment.

### 3. Result Analysis

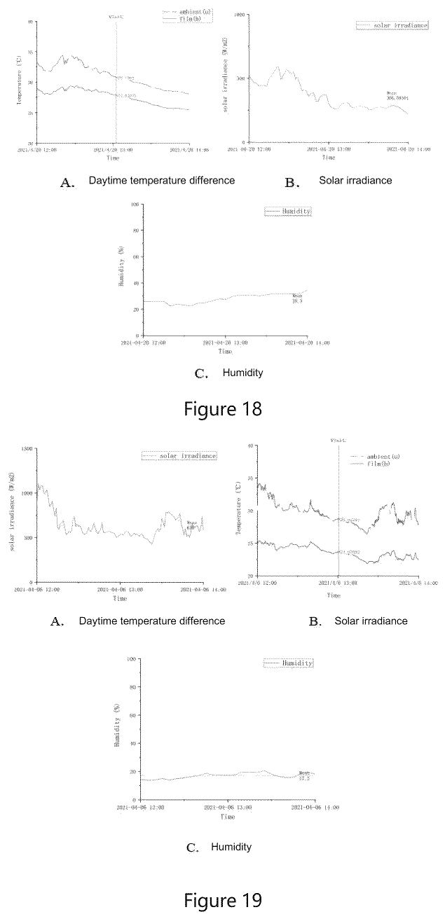

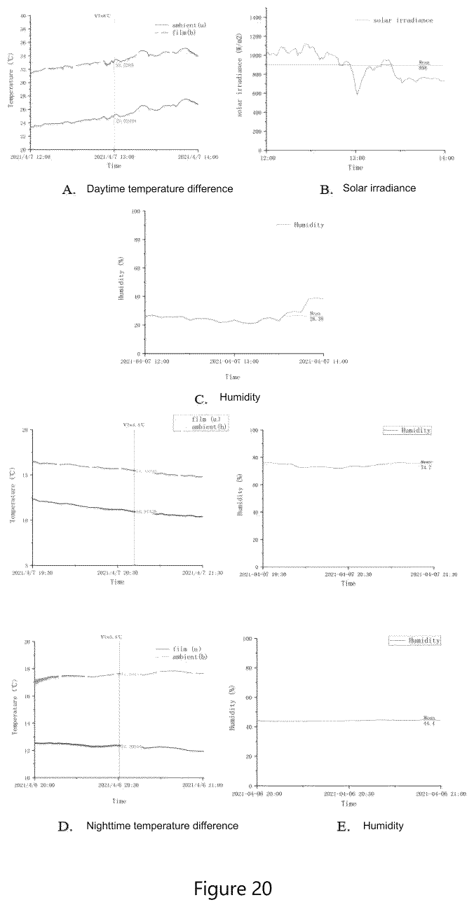

The daytime and nighttime temperature changes of the radiant film were measured under different weather conditions. During daytime measurement, the temperature of the side exposed to sunlight is higher. At this time, the ambient temperature on the film is the heat source. Therefore, the ambient temperature above the radiant film (Tambient-u) and the surface temperature under the radiative film (Tfilm-b) are selected as: Observation object, observe the cooling effect during the period of 12:00-14:00 when the sunlight is strongest; when measuring at night, the external ambient temperature is low, and the inside of the box is the heat source to be cooled. At this time, the ambient temperature under the radiation film is selected (Tambient-b), and the upper surface temperature of the radiation film (Tfilm-u) is the observation object. After sorting and analyzing the data, the results are as follows:
(1) cloudy day
It can be concluded from FIG. 18 that on a cloudy day, when the solar irradiance is 366.6 W/m² and the humidity is 28.3%, there is still a temperature difference of 3° C. between the cooling radiation film and the ambient temperature.
(2) Partly cloudy day
It can be seen from FIG. 19 that when it is cloudy, when the solar irradiance is 636 W/m² and the humidity is 17.2%, the temperature difference between the radiation film and the ambient temperature can reach 5° C.
(3) Clear day
It can be seen from FIG. 20 that when the weather is sunny, the solar irradiance is 898 W/m² and the relative humidity is 26.38%, the temperature difference between the radiative cooling film and the ambient temperature can reach 8° C. The humidity is relatively high at night. When the average humidity is 44.4%, the temperature difference is 5.5° C. When the humidity reaches 74.4%, the temperature difference drops to 4.5° C.

From FIGS. 18 to 20 that in rainless weather, the measured radiative cooling film can achieve a temperature difference of 3-8° C. whether during the day or at night. Currently, the maximum temperature difference measured during the day is 8° C., and the maximum temperature difference at night is 5.5° C.

Summary: Most of the nighttime temperature difference measurements in this part are carried out under clear conditions. The smallest temperature difference should occur during the day when the weather is bad. Experimental data can be supplemented if necessary. Limited by the infrared transmittance of ZnSe, the resulting temperature difference should be less than the optimal value that can be achieved.

### 2. Cooling Power Measurement Experiment

### 1. Device Introduction

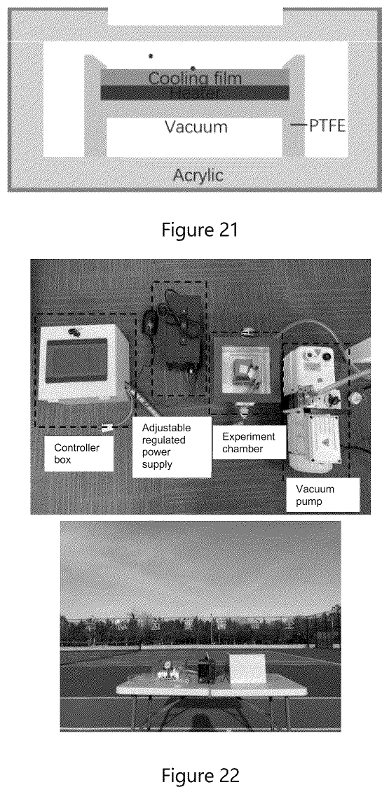

The cooling power measurement box is composed of a thermal insulation fixture, a heating plate, and a shell. The overall structure diagram is shown in FIG. 21. The main part of the box is designed and manufactured with 18 mm thick acrylic transparent plates. There is a 100×100 mm square working area in the center of the upper cover. The 12 mm thick acrylic plate is used, and the infrared transmittance can reach 90%. The radiative cooling film is pasted on the ceramic heating plate that can be heated evenly through thermal conductive silicone grease. The heating plate is placed on a polytetrafluoroethylene (PTFE) fixture and tightened to make it tightly connected to reduce the heat loss of the heating plate. The red dots in FIG. 21 are the placement points of the thermocouples, which measure the membrane upper surface temperature (T-film) and the ambient temperature (T-ambient), respectively.

### 2. Experimental Methods

We paste the 30 mm×30 mm radiative cooling film to be measured on the heating plate of the same size with thermal conductive silicone grease and arrange the K-type thermocouples according to the layout shown in FIG. 21. A programmable logic controller (PLC) integrated machine is used as the logic operation and control system. The integrated machine controls the intermediate components (for example: the DC voltage relay switch) to control the start and stop of the heating plate. After starting work, the PLC all-in-one machine measures the ambient temperature (ambient temperature, Ta) and film temperature (film temperature, Tf) for comparison. If the ambient temperature>film temperature, the PLC integrated machine controls the heating plate to heat the film with constant power until the ambient temperature=film temperature. The PLC all-in-one machine automatically collects the start-stop time ratio of the heating plate and the heating power of the heating plate and calculates the actual heating power of the heating plate during this period, which is the cooling power of the radiative cooling film. To reduce the influence of thermal conduction, measurements will be performed in a vacuum environment. The overall measurement system is shown in FIG. 22, including (from left to right in the figure) a control box, a DC adjustable voltage source, a withstand voltage test box and a vacuum pump.

### (1) Different Weather Conditions

The designed radiative cooling film cooling power measurement device was used to conduct measurement experiments on the cooling power of the designed nanostructure radiative cooling film under different weather conditions (sunny, cloudy). We assemble all parts of the device and check whether the connections are tight. We turn on the power and check whether the PLC all-in-one machine can operate normally and whether the thermocouple temperature reading is correct. The thermocouple reading is related to the ambient temperature and the connecting circuit, so the thermocouple needs to be calibrated. Place the entire device in an open and unobstructed outdoor place. First, we cover the window. When the temperature reading is stable, we start to calibrate the thermocouple through the control panel. After correction, the temperature difference between the radiative cooling film and the environment should be zero degrees. At this time, we remove the cover and start experimenting with things. It should be noted that after the obstruction is removed, the temperature on the film will drop rapidly, so the heating plate will quickly make up for this temperature difference at the beginning, which will cause the results to be too large, so the results in the first half hour are too large and not accurate enough. The power data should be extracted at least half an hour after the start, and the longer the experiment is carried out, the more accurate the results will be. The power measurement is performed simultaneously with the temperature measurement. Get the power corresponding to the reached temperature difference.

### (2) Fixed Temperature

The experiment is divided into four groups according to the preset specific temperatures, namely the 30° C. group, the 35° C. group, the 40° C. group, and the 45° C. group. The initial experimental steps are basically the same as the previous experiment. After calibrating the thermocouple, use a vacuum pump to evacuate the pressure-resistant shell and wait for the temperature of the PLC integrated machine to stabilize; we manually enter a fixed temperature value, and turn on the control switch, and the device is preheated, and when the temperature reaches the preset value, the device is restarted to start the experiment. We do each group for at least half an hour. The longer the time, the more accurate the results will be. After reaching the expected measurement time, we turn off the control switch and export the experimental data, and this is the end of one group of experiments. Enter different preset experimental environment temperatures, and repeat the above steps until all four groups have completed the measurement, which is the end of one experiment.

### 3. Result Analysis

### (1) Different Weather Conditions

### \textcircled{1} Measurement During the Day

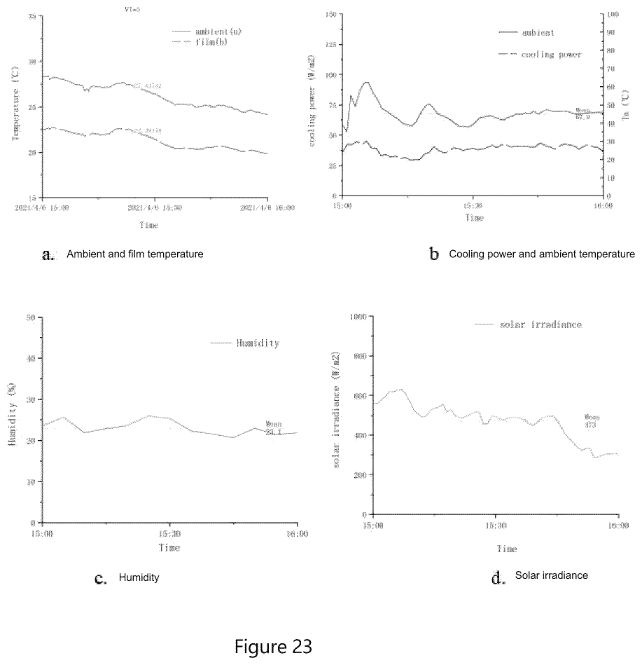

From FIG. 23 when it is cloudy, the ambient temperature is 25° C., and the average solar irradiance 473 W/m², when the humidity is 23.1%, the cooling power of the cooling radiant film is 67.9 W/m².

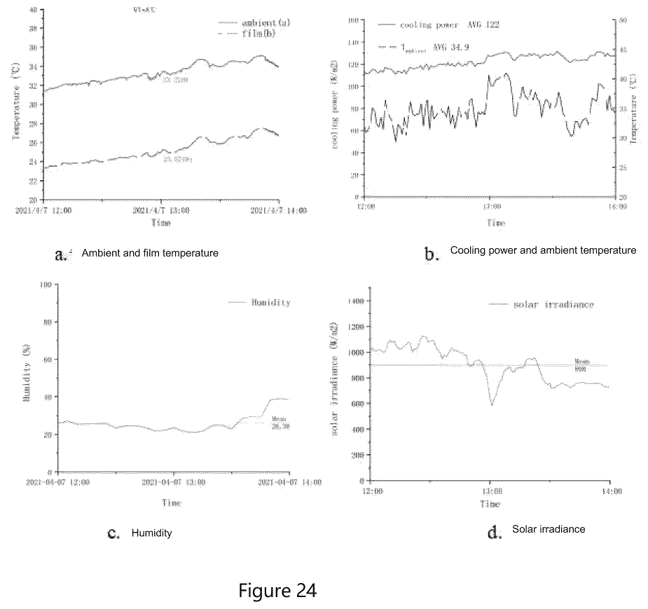

It can be seen from FIG. 24 that when the weather is sunny, the average solar irradiance is 898 W/m², the relative humidity is 26.4%, and the average ambient temperature is 34.9° C., the cooling power of the cooling radiant film can reach 122 W/m², the temperature difference corresponding to the expected power also increases to 8° C. Good weather conditions and increased ambient temperature are both reasons for increasing cooling power.

### \textcircled{2} Night Measurement

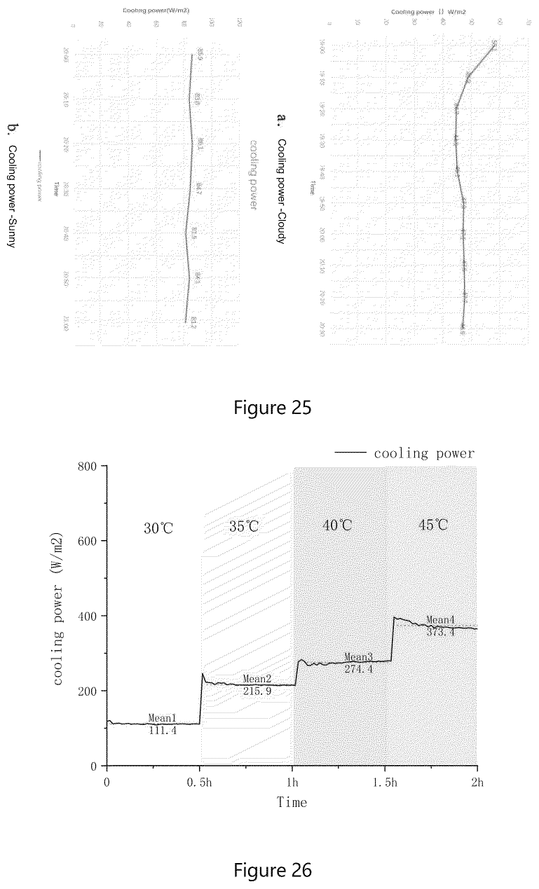

When the ambient temperature at night is 12° C., the cooling power of the radiant film is measured in cloudy and sunny weather, respectively, and the results are shown in FIG. 25. When it is cloudy, the power is 47.7 W/m², and when the weather is clear, the average power is 83.9 W/m². Much lower than the power of 67.9 W/m² and 122 W/m² when it is cloudy and sunny during the day. It can be seen that the ambient temperature has a great influence on the power of the radiant film, and a high operating temperature is more conducive to the effectiveness of the cooling radiant film.

### (2) Fixed Operating Temperature Power Measurement

The cooling power of the radiative cooling film at different operating temperatures is shown in FIG. 26. This experiment was conducted at night. Although the experiment was conducted under vacuum, the ambient temperature at night was low, and the temperature difference from the preset temperature was large, so the heat from the heating plate would also be radiated to the surrounding environment through the window. Therefore, the measured results are the result of the combined effect of the radiative cooling film and the surrounding environment. It cannot represent the cooling power of the radiative cooling film at this temperature, but it demonstrates the effect that the radiant film can achieve in application scenarios similar to experimental conditions.

The embodiment of the present invention provides a radiation refrigeration film with a periodic micro-nano structure on the surface. The absorption and radiation characteristics of the radiation refrigeration film in the visible light and infrared light bands are controlled by adding periodic micro-nano structures on the surface of the polymer film layer, which can increase the infrared radiation rate to effectively improve the radiation cooling performance and has a high market promotion value.

### Embodiment 2

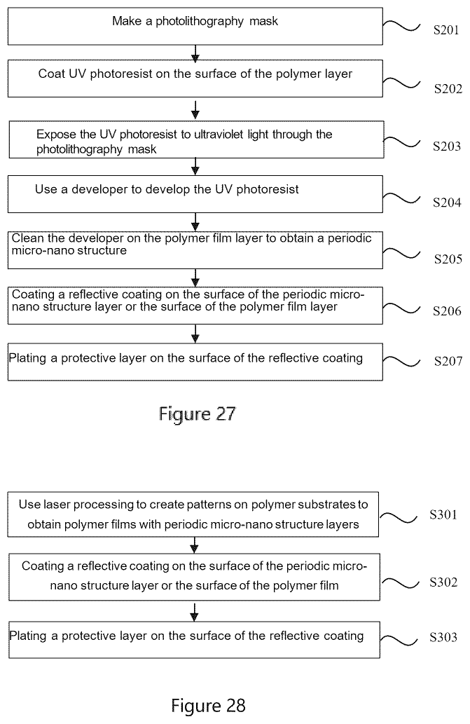

Please refer to FIG. 27. An embodiment of the present invention provides a method for preparing a radiative cooling film, which is used to prepare a radiative cooling film with a surface periodic micro-nano structure as described in the above-mentioned Embodiment 1. The method includes:
S201. Make a photolithography mask.
S202. Apply UV glue on the surface of the polymer film layer.
S203. Expose the UV glue to ultraviolet light through the photolithography mask.
S204. Use a developer to develop the UV glue.
S205. Clean the developer on the polymer film layer to obtain a periodic micro-nano structure layer.
S206. Coat a reflective coating on the surface of the periodic micro-nano structure layer or the surface of the polymer film layer.
S207. Plate a protective layer on the surface of the reflective coating.

The embodiments of the present invention provide a method for preparing a radiative cooling film, which uses ultraviolet lithography technology to add periodic micro-nano structures on the surface of the polymer film layer to control the absorption and radiation characteristics of the radiative cooling film in the visible light and infrared light bands. It can increase the infrared radiation to effectively improve the radiative cooling performance and has a high market promotion value.

### Embodiment 3

Please refer to FIG. 28. An embodiment of the present invention provides a method for preparing a radiative cooling film, which is used to prepare a radiative cooling film with a surface periodic micro-nano structure as described in the above-mentioned Embodiment 1. The method includes:
S301. Use laser processing to create patterns on the polymer substrate to obtain a polymer film with periodic micro-nano structure layers.
S302. Coat a reflective coating on the surface of the periodic micro-nano structure layer or the surface of the polymer film.
S303. Plate a protective layer on the surface of the reflective coating.

The embodiment of the present invention provides a method for preparing a radiative cooling film, which uses laser processing technology to add periodic micro-nano structures on the surface of the polymer film layer to control the absorption and radiation characteristics of the radiative cooling film in the visible light and infrared light bands. Increasing the infrared radiation rate to achieve effective improvement in radiative cooling performance has a high market promotion value.

1. A radiative cooling film with a periodic micro-nano structure on a surface thereof,
wherein the radiative cooling film comprises a periodic micro-nano structure layer, a polymer film layer, and a reflective coating;
wherein the periodic micro-nano structure layer, the polymer film layer, and the reflective coating are arranged in a first order or a second order from top to bottom; the first order being the periodic micro-nano structure layer, the polymer film layer, and the reflective coating, and the second order being the polymer film layer, the periodic micro-nano structure layer, and the reflective coating.

2. The radiative cooling film in accordance with claim 1, wherein the periodic micro-nano structure layer has periodically arranged air holes or periodically arranged dielectric pillars.

3. The radiative cooling film in accordance with claim 2, wherein the width of the periodically arranged air holes or periodically arranged dielectric pillars is 3˜8 μm, the period is 6˜12 μm, and the depth is 0.5˜5 μm.

4. The radiative cooling film in accordance with claim 1, wherein the polymer film layer is selected from the group consisting of polyethylene terephthalate, polyvinyl chloride, polycarbonate, polymethyl, methyl acrylate, polyvinylidene fluoride, and polypropylene.

5. The radiative cooling film in accordance with claim 1, wherein the reflective coating is a metal coating or a dielectric coating.

6. The radiative cooling film in accordance with claim 5, wherein the metal coating is an aluminum coating or a silver coating.

7. The radiative cooling film in accordance with claim 1, wherein the radiative cooling film further comprises a protective layer
located on a surface of the reflective coating away from the polymer film layer or the periodic micro-nano structure layer.

8. The radiative cooling film in accordance with claim 7, wherein the protective layer is an anti-fingerprint coating or a hard coating layer.

9. A method for preparing the radiative cooling film in accordance with claim 1, wherein the method comprises:
making a photolithography mask;
applying UV glue to the surface of the polymer film layer;
exposing the UV glue to UV light;
using a developer to develop the UV glue;
cleaning the developer on the polymer film layer to obtain a periodic micro-nano structure layer;
coating a surface of the periodic micro-nano structure layer or a surface of the polymer film layer with a reflective coating; and
plating a protective layer on a surface of the reflective coating.

10. A method for preparing the radiative cooling film in accordance with claim 1 wherein the method comprises:
using laser processing to create patterns on a first surface of the polymer film layer to obtain a periodic micro-nano structure layer;
coating a reflective coating on a surface of the periodic micro-nano structure layer or a second surface of the polymer film layer; and
plating a protective layer on a surface of the reflective coating.
